(19) United States
(12) Patent Application Publication
(10) Pub. No.: US 2026/0371721 A1
(43) Pub. Date: Nov. 19, 2026

(54) SEMICONDUCTOR ISOLATION STRUCTURE FOR INJECTION SUPPRESSION AND METHOD OF MAKING THEREOF

(71) Applicant: Taiwan Semiconductor Manufacturing Company, Ltd., Hsinchu (TW)

(72) Inventors: Tung-Yang Lin, New Taipei City (TW); Ruey-Hsin Liu, Hsin-Chu (TW); Liang-Yu Su, Yunlin County (TW)

(21) Appl. No.: 19/750,229

(22) Filed: Jul. 22, 2026

Related U.S. Application Data
(62) Division of application No. 18/673,792, filed on May 24, 2024.

(51) Int. Cl. H10D 84/85; H10D 84/01; H10D 84/03

(52) U.S. Cl. CPC H10D 84/854; H10D 84/0188; H10D 84/038

(57) ABSTRACT

Some embodiments relate to an integrated circuit (IC) structure having a low-resistivity P-type semiconductor substrate, an epitaxial layer that is substantially P-type doped on the semiconductor substrate, a first device region including a first transistor device in a first well of P-type doped semiconductor material in the epitaxial layer, a second device region in the epitaxial layer, and a deep trench isolation (DTI) structure interposed between the first device region and the second device region. The DTI structure extends through the epitaxial layer and includes a sidewall comprising a dielectric material and a N-type doped semiconductor fill conductively connected to the substrate.

### REFERENCE TO RELATED APPLICATION

This Application is a Divisional of U.S. application Ser. No. 18/673,792, filed on May 24, 2024, the contents of which are hereby incorporated by reference in their entirety.

### BACKGROUND

Many integrated circuits (ICs) include multiple transistor devices manufactured in variously doped regions of a semiconductor die. Field-effect transistors (FETs) use gates to control an electric field to regulate the flow of charge carriers in a channel region between source and drain regions of the FET. In some circumstances, charge carriers in the semiconductor die might flow in unintended paths and trigger malfunctions in the circuit.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a simplified schematic top view of a portion of an example integrated circuit in accordance with an embodiment of the disclosure.

FIG. 1B shows an embodiment of a simplified cross-sectional view of the portion of FIG. 1A along a cut line of FIG. 1A.

FIG. 1C shows an additional embodiment of a simplified cross-sectional view of the portion of FIG. 1B with some IC interconnectivity elements formed over the portion.

FIG. 1D shows an embodiment of a simplified cross-sectional view of an alternative implementation for the portion of FIGS. 1A and 1B.

FIG. 1E shows a simplified cross-sectional view of a portion of an integrated circuit in accordance with an embodiment of the disclosure and related to the portion of FIG. 1B.

FIG. 1F shows a simplified cross-sectional view of a portion of an integrated circuit in accordance with an alternative embodiment of the disclosure.

FIG. 1G shows a simplified cross-sectional view of a portion of an integrated circuit in accordance with an alternative embodiment of the disclosure.

FIG. 1H shows a simplified cross-sectional view of a portion of an integrated circuit in accordance with an alternative embodiment of the disclosure.

FIG. 1J shows a simplified cross-sectional view of a portion of an integrated circuit in accordance with an embodiment of the disclosure.

FIG. 1K shows a simplified cross-sectional view of a portion of an integrated circuit in accordance with an embodiment of the disclosure.

FIGS. 2-9 show simplified cross-sectional views of various example stages of manufacture of a deep trench isolation (DTI) structure in accordance with some embodiments of the disclosure.

FIG. 10 is a flowchart illustrating a method of forming a DTI structure in accordance with some embodiments of the disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A field-effect transistor (FET) uses voltage levels at a gate to control an electric field to regulate the flow of charge carriers in a channel region between source and drain regions of the FET. Source/drain region(s) may refer to a source or a drain, individually or collectively dependent upon the context. It should be noted that the source and drain of a FET may be collectively referred to as the current-carrying terminals of the FET, as distinct from the gate terminal of the FET. The current-carrying terminals may alternatively be referred to as charge-carrying terminals. In some circumstances, such as, for example, in the operation of high-power devices, which transmit relatively large currents, and particularly where they are adjacent to other devices, charge carriers in the semiconductor die embodying the high-power devices might be triggered to flow in unintended paths through the semiconductor die. The charge carriers flowing in unintended paths may consequently form parasitic transistor devices in the semiconductor die and cause latch-up or a similar malfunction involving the high-power device. A latch-up can be triggered by, for example, a voltage spike, a transient current, ionizing radiation, or a high temperature. The latch-up then leads to potentially excessive and uncontrolled current flows that can lead to overheating of the IC and/or permanent damage to the IC. Particular IC structures in the IC, adjacent to devices subject to latch-up, function to electrically isolate the devices subject to latch-up from other components of the IC by curtailing the flow of charge carriers in unintended paths, and can significantly reduce the likelihood of latch-up in the IC.

The present disclosure relates to an integrated chip structure that includes a deep trench isolation (DTI) structure that reduces a flow of charge carriers in unintended paths. In some embodiments, the IC structure comprises an epitaxial layer on a semiconductor substrate. The epitaxial layer comprises a first device region and a second device region. The first device region comprises a first transistor device disposed in a first well of doped semiconductor material in the epitaxial layer. A DTI structure is interposed between the first device region and the second device region. The DTI structure extends through the epitaxial layer and has a doped semiconductor fill arranged along a bottommost surface of the DTI structure. The doped semiconductor fill is configured to capture charge carriers in a vicinity of the bottom of the DTI structure, so as to prevent the charge carriers from moving along an unwanted path and thereby improve isolation between the first device region and the second device region. In some embodiments, the doped semiconductor fill may have a doping type that is complementary to that of the semiconductor substrate, so as to enhance isolation between the first device region and the second device region and to significantly reduce current injection (e.g., by more than one order of magnitude).

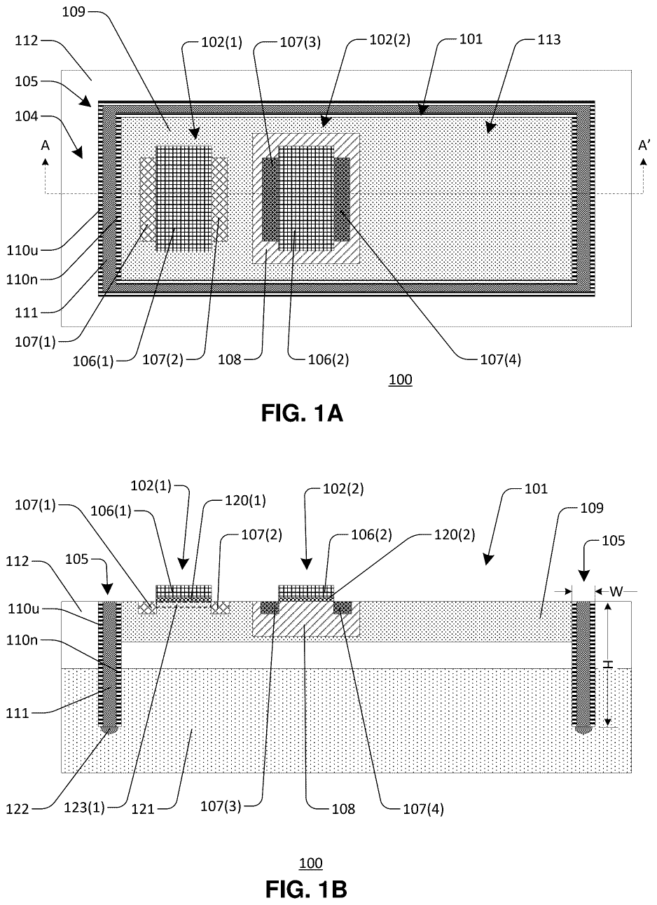

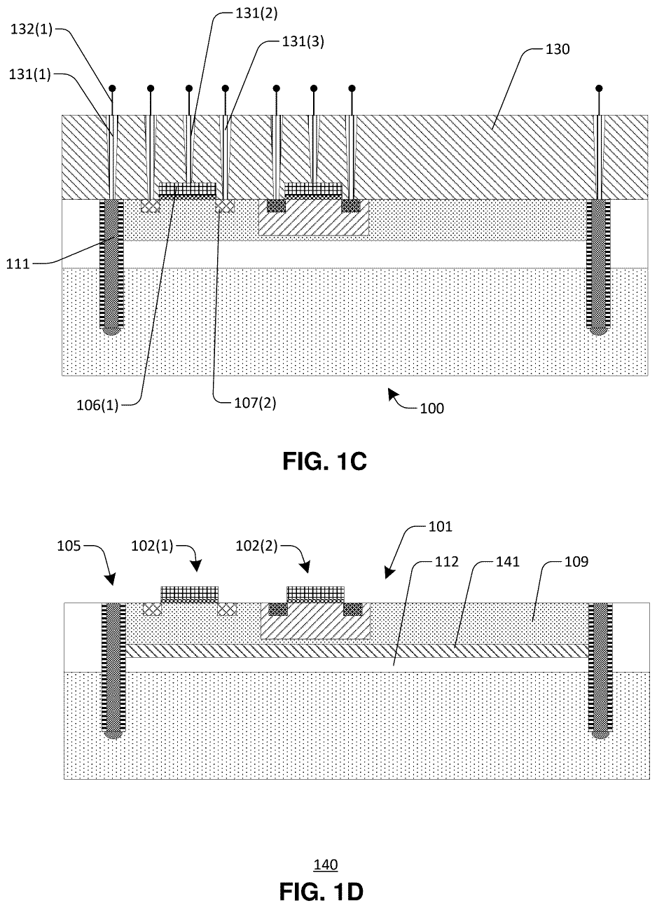

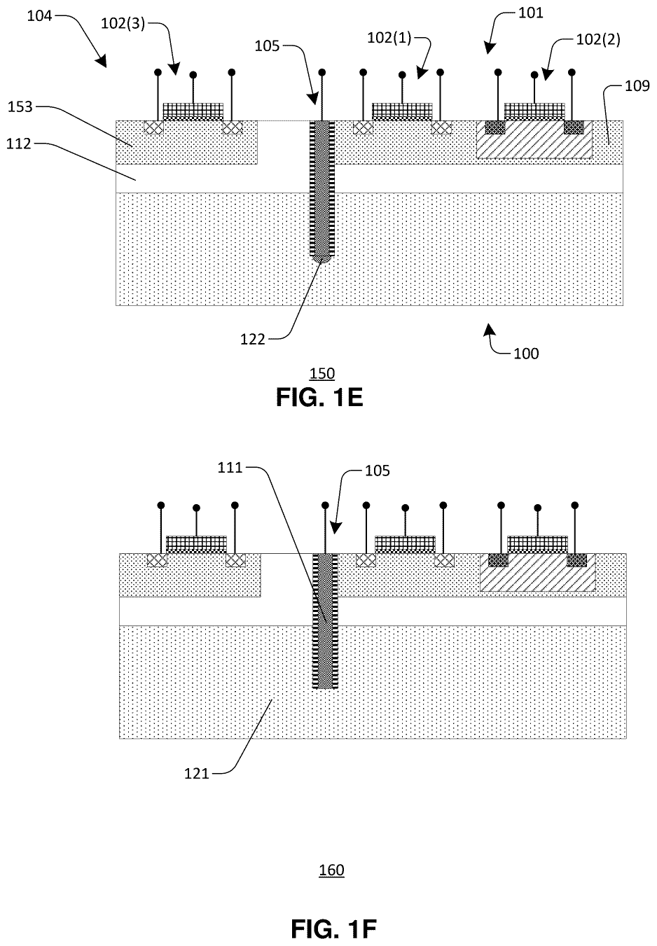

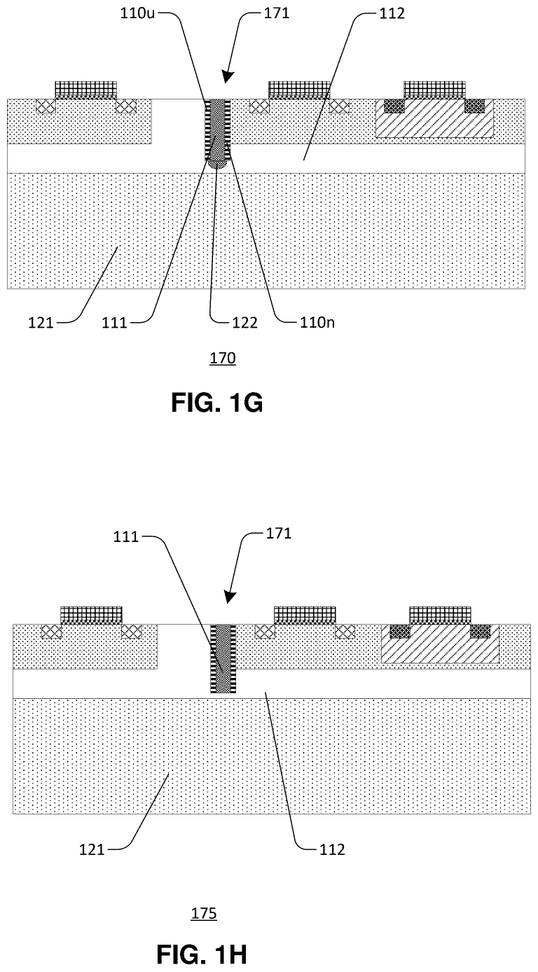

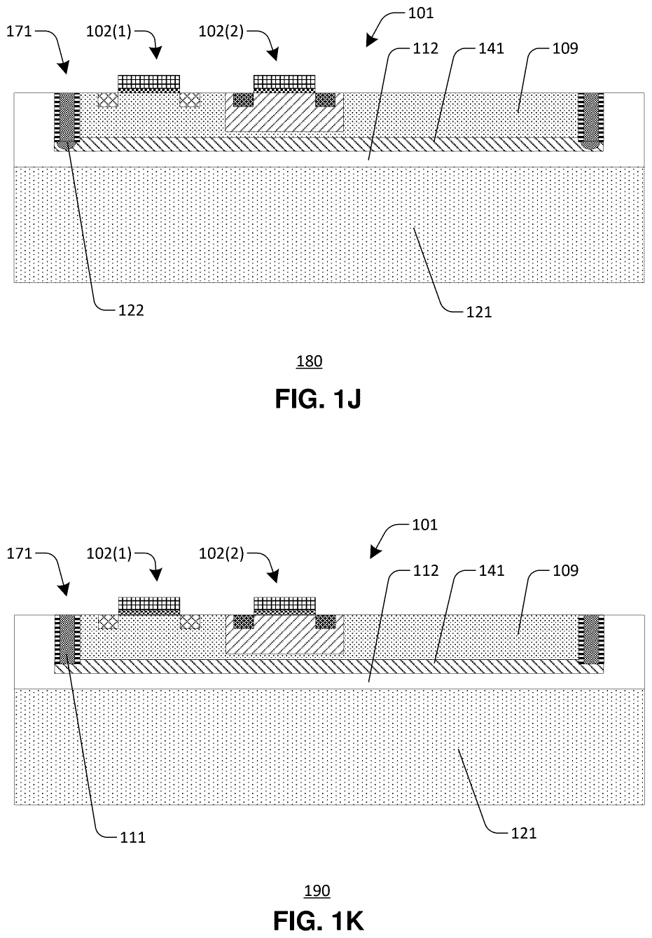

FIG. 1A illustrates a simplified schematic top view of a portion 100 of an example integrated circuit in accordance with an embodiment of the disclosure. Note that in FIG. 1A and the subsequent figures, different fill patterns for elements are intended to help visually distinguish different types of elements. Accordingly, unless otherwise indicated, different elements drawn with the same pattern fill may generally be presumed to share similar properties. The portion 100 includes a first device region 101 that includes a first transistor device 102(1) and a second transistor device 102(2). The portion 100 further includes a second device region 104 that is separated from the first device region 101 by deep trench isolation (DTI) structure 105. The deep trench isolation (DTI) structure 105 may form a moat laterally surrounding the first device region 101.

The first transistor device 102(1) comprises a gate terminal 106(1) and current-carrying terminals (e.g., source terminal and drain terminal) 107(1) and 107(2). The current-carrying terminals 107(1) and 107(2) are formed in a doped well 109 of an epitaxial layer 112. The doped well 109 may be moderately doped with a first-type dopant. The second transistor device 102(2) comprises a gate terminal 106(2) and current-carrying terminals (e.g., source terminal and drain terminal) 107(3) and 107(4). The current-carrying terminals 107(3) and 107(4) are formed in a doped well 108 formed in the doped well 109. For a particular transistor device 102, the current-carrying terminal 107 that functions as a source is the terminal through which the corresponding charge carriers (e.g., electrons or holes) enter the transistor device 102. Correspondingly, the current-carrying terminal 107 that functions as a drain is the terminal through which the corresponding charge carriers (e.g., electrons or holes) leave the transistor device 102. The determinations of source and drain depend on the charge carriers for a particular transistor device 102 and the circuit elements to which the transistor device 102 is connected. In some implementations, current-carrying terminals 107(2) and 107(3) are drain terminals and current-carrying terminals 107(1) and 107(4) are source terminals.

The DTI structure 105 that is interposed between the first device region 101 and the second device region 104 comprises an inner dielectric sidewall 110n, an outer dielectric sidewall 110u (collectively, dielectric sidewalls 110), and a doped semiconductor fill 111. The second device region 104 comprises epitaxial layer 112, which may be lightly doped. The first device region 101 further comprises area 113, which may contain additional transistor devices (not shown) or other active or passive IC elements (not shown).

FIG. 1B shows a simplified cross-sectional view of an embodiment of the portion 100 of FIG. 1A along cut line A-A′ of FIG. 1A, which illustrates some additional features of the portion 100. Epitaxial layer 112 is formed over a semiconductor substrate 121. Semiconductor substrate 121 may comprise, for example, monocrystalline silicon on which the epitaxial layer 112 is grown. Alternatively, the semiconductor substrate 121 can comprise a binary semiconductor substrate (e.g., GaAs), a tertiary semiconductor substrate (e.g., AlGaAs), or a higher order semiconductor substrate. The semiconductor substrate 121 may be heavily doped with a first-type dopant to make it a low-resistivity (or a high conductivity) substrate. In some implementations, the semiconductor substrate 121 may be heavily doped with a P-type dopant such as, for example, boron (B), aluminum (Al), indium (In), gallium (Ga) or any suitable P-type dopant, to form a low-resistivity P++ substrate. In some implementations, the heavily doped semiconductor substrate 121 has a dopant concentration of at least 10²⁰ atoms per cubic centimeter (10²⁰/cm³), at least 10¹⁹/cm³, or other similar values. Note that in some alternative implementations the semiconductor substrate 121 has a lower dopant concentration, which is less costly to produce than the above-described concentration, and, additionally, may be categorized as enhanced (P+) or moderately (P) doped.

The epitaxial layer 112 may be lightly doped with a first-type dopant. In some implementations, epitaxial layer 112 is lightly doped with a P-type dopant such as, for example, boron (B), aluminum (Al), indium (In), gallium (Ga) or any suitable P-type dopant, to form a lightly doped P-epitaxial layer 112. In some implementations, the lightly doped epitaxial layer 112 has a dopant concentration of between approximately 10¹⁴ and 10¹⁵ atoms per cubic centimeter (10¹⁴/cm³-10¹⁵/cm³), between approximately 10¹⁴/cm³ and 10¹⁶/cm³, or other similar values. The epitaxial layer 112 may be doped using, for example, in-situ doping during deposition, post-deposition diffusion, ion implantation, and/or any other suitable doping method.

The doped well 109 may be formed by, for example, adding dopant to the first device region 101 of the epitaxial layer 112. The well 109 may be doped using, for example, diffusion, ion implantation, and/or any other suitable doping method. In some implementations, the well is moderately doped with a P-type dopant such as, for example, boron (B), aluminum (Al), indium (In), gallium (Ga) or any suitable P-type dopant, to form a P well 109. In some implementations, the moderately doped P well 109 has a dopant concentration of between approximately 10¹⁵ and 10¹⁶ atoms per cubic centimeter (10¹⁵/cm³-10¹⁶/cm³), between approximately 10¹⁵/cm³ and 10¹⁷/cm³, or other similar values.

The DTI structure 105, which comprises dielectric sidewalls 110n and 110u and doped semiconductor fill 111, extends through the epitaxial layer 112 and into the semiconductor substrate 121. In some implementations, the DTI structure 105 has a high aspect ratio wherein the ratio of its height H to its width W, in a cross-sectional view, is at least 4:1. The dielectric sidewalls 110, which provide electrical isolation for adjacent portions of the doped semiconductor fill 111, may comprise silicon dioxide (SiO2), silicon nitride (Si₃N₄), or other suitable dielectric material. The doped semiconductor fill 111 may be polycrystalline silicon, commonly known as polysilicon or poly. The doped semiconductor fill 111 may be enhanced doped with a complementary-type dopant, where the dopant type is complementary to the first-type dopant. For example, if the first-type dopant is a P-type dopant (e.g., P−, P, P+, or P++), then the complementary-type dopant would be an N-type dopant (e.g., N−, N, N+, or N++). Conversely, if the first-type dopant is an N-type dopant (e.g., N−, N, N+, or N++), then the complementary-type dopant would be a P-type dopant (e.g., P−, P, P+, or P++).

In some implementations, the doped semiconductor fill 111 may be enhanced N-type doped (N+) polysilicon doped with an N-type dopant such as, for example, phosphorous (P), antimony (Sb), arsenic (As), or the like. In some implementations, the enhanced doped semiconductor fill 111 has a dopant concentration of between approximately 10¹⁶ and 10²⁰ atoms per cubic centimeter (10¹⁶/cm³-10²⁰/cm³). The doped semiconductor fill 111 may be doped using, for example, in-situ doping during deposition, post-deposition diffusion, ion implantation, and/or any other suitable doping method.

In some implementations, a heavy dopant concentration (e.g., P++) is at least one order of magnitude greater than an enhanced dopant concentration (e.g., P+), which is, in turn, at least one order of magnitude greater than a moderate dopant concentration (e.g., P), which is, in turn, at least one order of magnitude greater than a light dopant concentration (e.g., P−). For example, in one particular example implementation, the heavy, enhanced, moderate, and light dopant concentrations may be, respectively, approximately 10²⁰/cm³, 10¹⁹/cm³, 10¹⁵/cm³, and 10¹⁴/cm³. In another example implementation, the heavy, enhanced, moderate, and light dopant concentrations may be, respectively, approximately 10¹⁹/cm³, 10¹⁸/cm³, 10¹⁷/cm³, and 10¹⁶/cm³.

The neighboring region 122 of the semiconductor substrate 121, which is contiguous with the doped semiconductor fill 111—and, optionally, also contiguous with a portion of the dielectric sidewalls 110—may be enhanced doped with the same type dopant as the semiconductor fill 111, which is a complementary-type dopant. This doping of the neighboring region 122 may enhance the DTI structure's ability to capture charge carriers in the vicinity of the bottom of the DTI structure 105 and prevent them from forming unwanted current pathways in the portion 100 of the integrated circuit. In some embodiments, the neighboring region 122 may be laterally set back from outermost edges of the dielectric sidewalls 110 that face away from the doped semiconductor fill 111 by non-zero distances. In some embodiments, the neighboring region 122 may have an outer edge that is directly below the dielectric sidewalls 110. In some embodiments, the neighboring region 122 may extend to a maximum depth directly below the doped semiconductor fill 111 and smaller depths laterally outside of the doped semiconductor fill 111.

In some implementations, the neighboring region 122 may be enhanced N-type doped (N+) with an N-type dopant such as, for example, phosphorous (P), antimony (Sb), arsenic (As), or any suitable N-type dopant. In some implementations, the enhanced doped neighboring region 122 has a dopant concentration of between approximately 10¹⁶ and 10²⁰ atoms per cubic centimeter (10¹⁶/cm³-10²⁰/cm³). The neighboring region 122 may be doped using, for example, in-situ doping during deposition, post-deposition diffusion, ion implantation, and/or any other suitable doping method. An implementation as described above, having a DTI structure with an N+ polysilicon fill and optional N+ neighboring region, is particularly useful in suppressing substrate injection of negative charge carriers (electrons), which is particularly beneficial for preventing latch-up.

In a transistor device 102, the gate terminal 106 may comprise a metal such as, for example, copper or aluminum, highly conductive doped polysilicon, or any other suitable conductive material. The gate terminal 106 may be formed over a corresponding gate dielectric layer 120 separating the gate terminal 106 from the corresponding channel zone 123 in the well 109 or 108. For example, the gate terminal 106(1) of the first transistor device 102(1) is separated from the channel zone 123(1) in the well 109 of the epitaxial layer 112 by the gate dielectric layer 120(1). The gate dielectric layer 120 may comprise, for example, silicon dioxide (SiO₂), silicon nitride (Si₃N₄), silicon oxynitride, carbon doped silicon oxide, other suitable dielectric materials, or combinations thereof. In some implementations, the gate dielectric layer 120 may include a high-k dielectric material, such as, for example, hafnium oxide (HfO₂), zirconium oxide (ZrO₂), aluminum oxide (Al₂O₃), hafnium silicon oxide (HfSiO), hafnium silicon oxynitride (HfSiON), hafnium tantalum oxide (HfTaO), hafnium titanium oxide (HfTiO), hafnium titanium tantalum oxide (HfTiTaO), hafnium aluminum oxynitride (HfAlON), hafnium zirconium oxide (HfZrO), other suitable high-k dielectric materials, or combinations thereof.

In one implementation, transistor device 102(1) is an N-channel metal-oxide-semiconductor (NMOS) FET and transistor device 102(2) is a P-channel metal-oxide-semiconductor (PMOS) FET. The transistor devices 102(1) and 102(2) may be high-power transistor devices. Notably, alternative implementations of the transistor devices 102(1) and 102(2) may have somewhat different structures and geometries optimized for handling large current flows. The NMOS transistor device 102(1) includes the enhanced N-type (N+) doped current-carrying (e.g., source and drain) terminals 107(1) and 107(2) that may be doped with an N-type dopant such as, for example, phosphorous (P), antimony (Sb), arsenic (As), or any suitable N-type dopant. In some implementations, the enhanced N-type doped (N+) current-carrying terminals 107(1) and 107(2) have a dopant concentration of between approximately 10¹⁶ and 10²⁰ atoms per cubic centimeter (10¹⁶/cm³-10²⁰/cm³). The current-carrying terminals 107(1) and 107(2) may be doped using, for example, diffusion, ion implantation, and/or any other suitable doping method.

Correspondingly, in the same implementation, the PMOS transistor device 102(2) includes the enhanced P-type (P+) doped current-carrying (e.g., source and drain) terminals 107(3) and 107(4) that may be doped with an P-type dopant such as, for example, boron (B), aluminum (Al), indium (In), gallium (Ga) or any suitable P-type dopant. The current-carrying terminals 107 of the PMOS transistor device are formed in the doped well 108, formed inside the above-described P well 109, which may be moderately doped with N-type dopant such as, for example, phosphorous (P), antimony (Sb), arsenic (As), or any suitable N-type dopant, to form an N well 108. The N well 108 may be doped using, for example, diffusion, ion implantation, and/or any other suitable doping method. In some implementations, the moderately doped N well 108 has a dopant concentration of between approximately 10¹⁵ and 10¹⁶ atoms per cubic centimeter (10¹⁵/cm³-10¹⁶/cm³). Meanwhile, the enhanced P-type doped (P+) current-carrying terminals 107(3) and 107(4) have a dopant concentration of between approximately 10¹⁶ and 10²⁰ atoms per cubic centimeter (10¹⁶/cm³-10²⁰/cm³). The current-carrying terminals 107(1) and 107(2) may be doped using, for example, diffusion, ion implantation, and/or any other suitable doping method.

FIG. 1C shows an embodiment of a simplified cross-sectional view of the portion 100 of FIG. 1B with some IC interconnectivity (or interconnect layer) elements over the portion 100. Specifically, FIG. 1C shows an inter-layer dielectric (ILD) 130 over the components of the portion 100 and conductive vias 131—such as example conductive vias 131(1), 131(2), and 131(3)—that connect various components of the portion 100—such as, respectively, doped semiconductor fill 111, gate terminal 106(1) and current-carrying terminal 107(2)—to the first metallization layer (M1) (not shown) through the ILD 130. The ILD 130 may be formed, by, for example, chemical vapor deposition (CVD), plasma vapor deposition (PVD), spin on techniques, thermal oxidation, or any suitable technique. The conductive vias 131 may be connected to other conductive vias, ground, a power rail, a device operating voltage, or other electrically conductive features via the schematically illustrated contacts 132, such as contact 132(1). In some implementations, the contact 132(1) connects the doped semiconductor fill 111 to a ground, or common, voltage via the conductive via 131(1). In some implementations, the contact 132(1) is configured to connect to a non-zero voltage to provide, for example, a small positive bias to the doped semiconductor fill 111 via the conductive via 131(1). The voltage connection to the doped semiconductor fill 111 is intended to help capture charge carriers by the bottom of the doped semiconductor fill 111 to prevent those charge carriers from forming unintended current paths in the portion 100.

The conductive vias 131 may comprise metal such as, for example, copper, aluminum, tungsten, or the like. The ILD 130 may comprise, for example, low-k dielectrics (e.g., a dielectric material with a dielectric constant less than about 3.9), oxides (e.g., SiO2), nitrides (e.g., SiN), carbides (e.g., SiC), oxy-nitrides (e.g., SiON), oxy-carbides (e.g., SiOC), undoped silicate glass (USG), doped silicon dioxide (e.g., carbon doped silicon dioxide), borosilicate glass (BSG), phosphoric silicate glass (PSG), borophosphosilicate glass (BPSG), fluorinated silicate glass (FSG), a spin-on glass (SOG), or the like.

FIG. 1D shows a simplified cross-sectional view of an alternative implementation 140 for the portion 100 of FIGS. 1A and 1B. Specifically, the alternative implementation 140 includes a buried doped barrier layer 141 underneath and in contact with the doped well 109. The buried doped barrier layer 141 may be moderately doped with a complementary-type dopant. In some implementations, where the doped well 109 is a P-type-doped well, the buried doped barrier layer 141 is moderately doped with N-type dopant such as, for example, phosphorous (P), antimony (Sb), arsenic (As), or any suitable N-type dopant, to form an N buried layer (NBL). In some implementations, the moderately doped N buried layer has a dopant concentration of between approximately 10¹⁵ and 10¹⁶ atoms per cubic centimeter (10¹⁵/cm³-10¹⁶/cm³). The N buried layer is doped using, for example, in-situ doping during deposition, post-deposition diffusion, ion implantation, optionally including annealing, and/or any other suitable doping method. The doped barrier layer 141 functions to help electrically isolate active devices in the first device region 101 from devices outside of the first device region 101 as the formed junction makes it more difficult for charge carriers to cross over the doped barrier layer 141.

FIG. 1E shows a simplified cross-sectional view of a portion 150 of an integrated circuit in accordance with an embodiment of the disclosure and related to the portion 100 of FIG. 1B. Portion 150 may be considered a shifted view of the view shown in FIG. 1B where portion 150 shows a transistor device 102(3) in the second device region 104. The transistor device 102(3), formed in a doped well 153 in the epitaxial layer 112, is substantially the same as the transistor device 102(1) described above. The well 153 is substantially the same as the well 109 described above. The DTI structure 105 helps prevent the unintended flow of charge carriers from transistor devices 102(1) and 102(2) to transistor device 102(3). As would be appreciated by one of ordinary skill in the art, the second device region 104 may comprise additional transistor devices (not shown) such as, for example, transistor devices similar to transistor device 102(2).

FIG. 1F shows a simplified cross-sectional view of a portion 160 of an integrated circuit in accordance with an alternative embodiment of the disclosure. The portion 160 is substantially similar to the portion 150 of FIG. 1E described above, but without the neighboring region 122. Forgoing forming a neighboring region 122—in other words, skipping the attendant photolithography and doping steps—reduces the cost of manufacturing an integrated circuit in accordance with the disclosure. As the bottom of the doped semiconductor fill 111 remains in direct contact with the semiconductor substrate 121, the doped semiconductor fill 111 functions to capture charge carriers in the vicinity of the bottom of the doped semiconductor fill 111 and prevent them from forming unwanted current pathways in the portion 160 of the integrated circuit. Accordingly, the neighboring region 122 may be considered an optional feature for any of the previous implementations described herein.

FIG. 1G shows a simplified cross-sectional view of a portion 170 of an integrated circuit in accordance with an alternative embodiment of the disclosure. The portion 170 is substantially similar to the portion 150 of FIG. 1E described above, but where the DTI structure 171 is shallower than the DTI structure 105 of FIG. 1E and the preceding figures. Specifically, the shallower DTI structure 171—including outer dielectric sidewall 110u, inner sidewall 110n, and doped semiconductor fill 111—extends through, but also terminates in, the epitaxial layer 112. The shallower DTI structure 171, due to its lesser depth and forgoing etching into the semiconductor substrate 121, would be simpler, faster, and less costly to form than the DTI structure 105 of FIG. 1E. The shallower DTI structure 171 may be formed using substantially the same techniques described elsewhere in reference to forming the deeper DTI structure 105 of FIG. 1E. The shallower DTI structure 171 also includes a neighboring region 122 that is substantially the same as—and may be formed in substantially the same way as—the above-described neighboring region 122 of FIG. 1B and subsequent figures.

FIG. 1H shows a simplified cross-sectional view of a portion 175 of an integrated circuit in accordance with an alternative embodiment of the disclosure. The portion 175 is substantially similar to the portion 170 of FIG. 1G described above, but without the neighboring region 122. Forgoing forming a neighboring region 122—in other words, skipping the attendant photolithography and doping steps—reduces the cost of manufacturing an integrated circuit in accordance with the disclosure. As the bottom of the doped semiconductor fill 111 remains in direct contact with the epitaxial layer 112, the doped semiconductor fill 111 functions to capture charge carriers in the vicinity of the bottom of the doped semiconductor fill 111 and prevent them from forming unwanted current pathways in the portion 175 of the integrated circuit. Accordingly, the neighboring region 122 may be considered an optional feature for the shallower DTI structure 171.

FIG. 1J shows a simplified cross-sectional view of a portion 180 of an integrated circuit in accordance with an embodiment of the disclosure. The portion 180 combines some features of portion 140 of FIG. 1D and portion 170 of FIG. 1G. Specifically, the portion 180 combines the buried doped barrier layer 141 as described in reference to FIG. 1D with the shallower DTI structure 171 as described in reference to FIG. 1G. In the embodiment pictured in FIG. 1J, the DTI structure 171 terminates within the buried doped barrier layer 141 and the neighboring region 122 is formed within the buried doped barrier layer 141. In other implementations (not shown), the DTI structure may extend past the buried doped barrier layer 141 and terminate within the epitaxial layer 112, where the neighboring region 122 may also be formed. The benefits of a buried doped barrier layer and of a shallower DTI structure, which come at the expense of greater complexity and production cost, have been described above in reference to the corresponding elements of FIGS. 1D and 1G and generally also apply to the portion 180 of FIG. 1J. Additional benefits for the prevention of parasitic currents may accrue from the location of the neighboring region 122 in the buried doped barrier layer 141.

FIG. 1K shows a simplified cross-sectional view of a portion 190 of an integrated circuit in accordance with an embodiment of the disclosure. The portion 190 combines some features of portion 140 of FIG. 1D and portion 175 of FIG. 1H. Specifically, the portion 190 combines the buried doped barrier layer 141 as described in reference to FIG. 1D with the shallower DTI structure of FIG. 1H, which lacks a neighboring region and where, consequently, the bottom of the doped semiconductor fill 111 is in contact with the epitaxial layer. In the embodiment pictured in FIG. 1K, the DTI structure 171 terminates within the buried doped barrier layer 141 and the bottom of the doped semiconductor fill 111 is in contact specifically with the buried doped barrier layer 141 formed in the epitaxial layer. The benefits of a buried doped barrier layer and of a shallower DTI structure, which come at the expense of greater complexity and production cost, have been described above in reference to FIGS. 1D and 1G and generally also apply to the portion 190 of FIG. 1K. Similarly, the benefits of forgoing the neighboring region 122 have been described above in reference to FIG. 1H and generally also apply to the portion 190 of FIG. 1K.

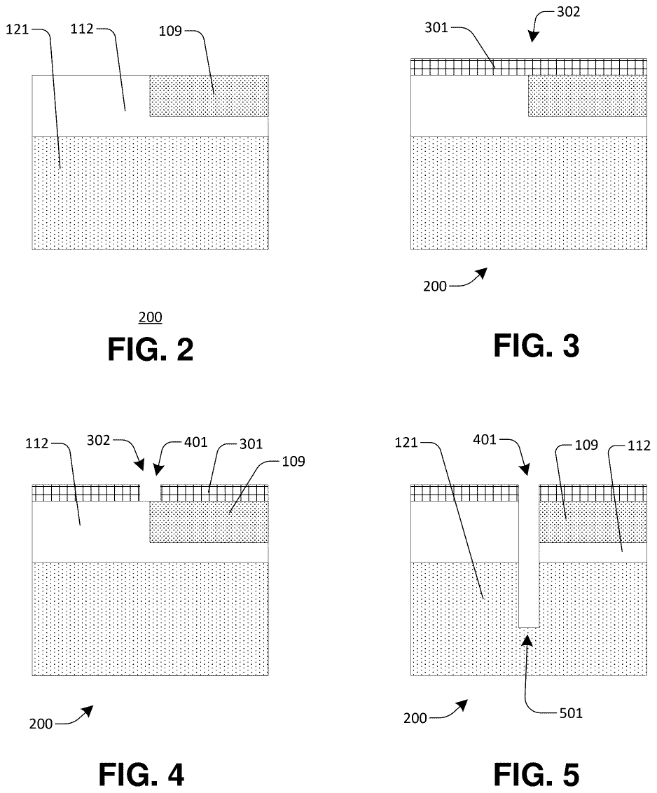

FIGS. 2-9 show simplified cross-sectional views of various example stages of manufacture of a DTI structure in accordance with some embodiments of the disclosure. Although FIGS. 2-9 are described as a series of acts, it will be appreciated that these acts are not limiting in that the order of the acts can be altered in other embodiments, and the methods disclosed are also applicable to other structures. In some embodiments, some acts that are illustrated and/or described may be omitted in whole or in part. In some embodiments, additional acts that are not described herein may also be performed as part of the manufacturing process.

FIG. 2 shows a simplified cross-sectional view of a portion 200 of a wafer comprising a semiconductor substrate 121, an epitaxial layer 112 formed over the substrate and a first-type-doped well 109 formed in the epitaxial layer 112. The semiconductor substrate 121 may be doped using, for example, diffusion, ion implantation, optionally including annealing, and/or any other suitable doping method. The epitaxial layer 112 may be grown over the semiconductor substrate 121 using, for example, chemical vapor deposition (CVD), plasma enhanced CVD (PECVD), or any suitable deposition technique.

FIG. 3 shows a cross-sectional view of the portion 200 of FIG. 2 after it has been overlaid with a mask layer 301, which may be a suitable photoresist or hardmask layer that may be deposited via a spin coating process, a deposition process, or the like. In an implementation where the mask layer 301 comprises a photoresist, a photolithographic process may be executed wherein the mask layer 301 is selectively exposed to electromagnetic radiation based on a photo mask, whereupon the electromagnetic radiation modifies a solubility of exposed regions of the mask layer 301 to define soluble regions, such as region 302.

FIG. 4 shows a cross-sectional view of the portion 200 of FIG. 3 after the removal of the soluble region 302 of the mask layer 301 to define an opening 401 in the mask layer 301 corresponding with the region 302. In some embodiments, the region 302 may be removed by exposing the mask layer 301 to a developer that dissolves the region 302.

FIG. 5 shows a cross-sectional view of the portion 200 of FIG. 4 after the formation of a trench 501 defined by the opening 401 in the mask layer 301. The trench 501 may be formed by, for example, dry etching of the epitaxial layer 112 and the semiconductor substrate 121 with, for example, a dry etchant such as, for example, a gaseous mixture of xenon and fluoride (e.g., XeF₆), sulfur and fluoride (e.g., SF₆), or some other suitable mixture.

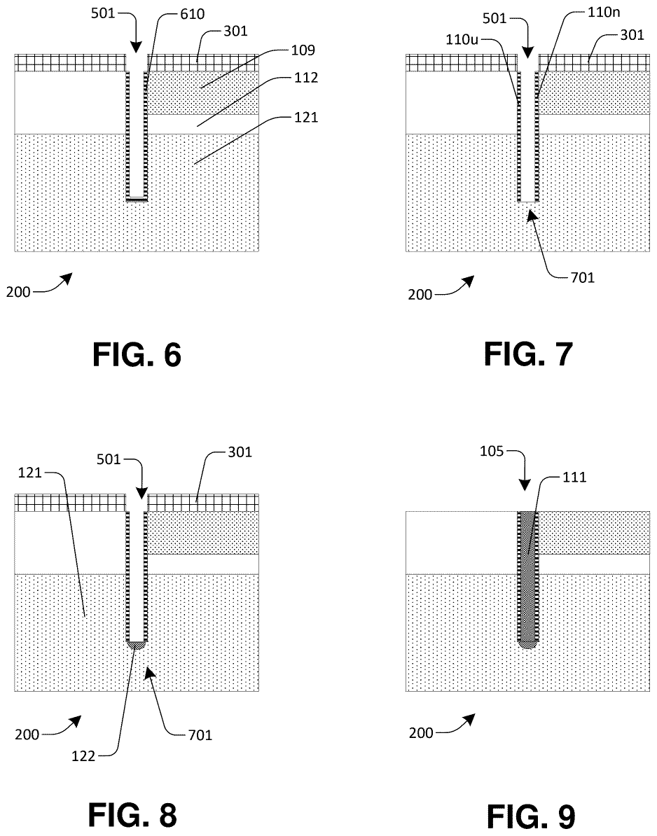

FIG. 6 shows a cross-sectional view of the portion 200 of FIG. 5 after the formation of dielectric sidewall structure 610 coating the surfaces of the trench 501. The sidewall structure 610 may comprise, for example, silicon dioxide and may be formed by any suitable deposition technique (e.g., a deposition process, a thermal oxidation process, etc.). In some embodiments, the masking layer 301 may be kept in place over the epitaxial layer to block formation of the dielectric sidewall structure 610 along a top surface of the epitaxial layer.

In some embodiments (not shown), a thickness of the dielectric sidewall structure 610 may be substantially constant over a height of the dielectric sidewall structure 610. In other embodiments, a thickness of the dielectric sidewall structure 610 may vary over a height of the dielectric sidewall structure 610. For example, in some embodiments the dielectric sidewall structure 610 may have a first thickness along sidewalls of the semiconductor substrate 121, a different second thickness along sidewalls of the epitaxial layer 112 that are below the first-type-doped well 109, and a different third thickness along sidewalls of the first-type-doped well 109. In some embodiments, the first thickness may be larger than the second thickness and the second thickness may be smaller than the third thickness.

FIG. 7 shows a cross-sectional view of the portion 200 of FIG. 6 following the removal of the bottom portion of the sidewall structure 610 at the bottom 701 of the trench 501, leaving behind outer dielectric sidewall 110u and inner dielectric sidewall 110n. The bottom of the sidewall structure 610 may be removed by, for example, an etching process. Note that this etching process may use a different chemistry from the etching process described in reference to FIG. 5 as each etch may have a particular corresponding chemistry to be selective for particular corresponding materials. In some embodiments, the masking layer 301 may be kept in place over the epitaxial layer to prevent etching of a top surface of the epitaxial layer.

FIG. 8 shows a cross-sectional view of the portion 200 of FIG. 7 following the enhanced doping of the semiconductor substrate 121 in the region neighboring the bottom of the trench 501 to form the neighboring region 122. The neighboring region 122 may be doped using, for example, diffusion, ion implantation, or any suitable doping technique. In some embodiments, the masking layer 301 may be kept in place over the epitaxial layer to block implantation of the dopants into a top surface of the epitaxial layer.

FIG. 9 shows a cross-sectional view of the portion 200 of FIG. 8 following the deposition of doped semiconductor fill 111 in the trench 501 to form the DTI structure 105. The doped semiconductor fill 111 may be deposited using, for example, CVD or any suitable deposition technique. In some embodiments, after formation of the doped semiconductor fill 111 in the trench 501, a planarization process may be performed to remove the masking layer (e.g., 301 of FIG. 8) and a part of the doped semiconductor fill 111 that is outside of the trench 501. In some embodiments, the planarization process may comprise a chemical mechanical planarization (CMP) process, an etching process, or the like.

After the above-described wafer processing is completed, the wafer may be singulated into individual die which correspond to individual ICs.

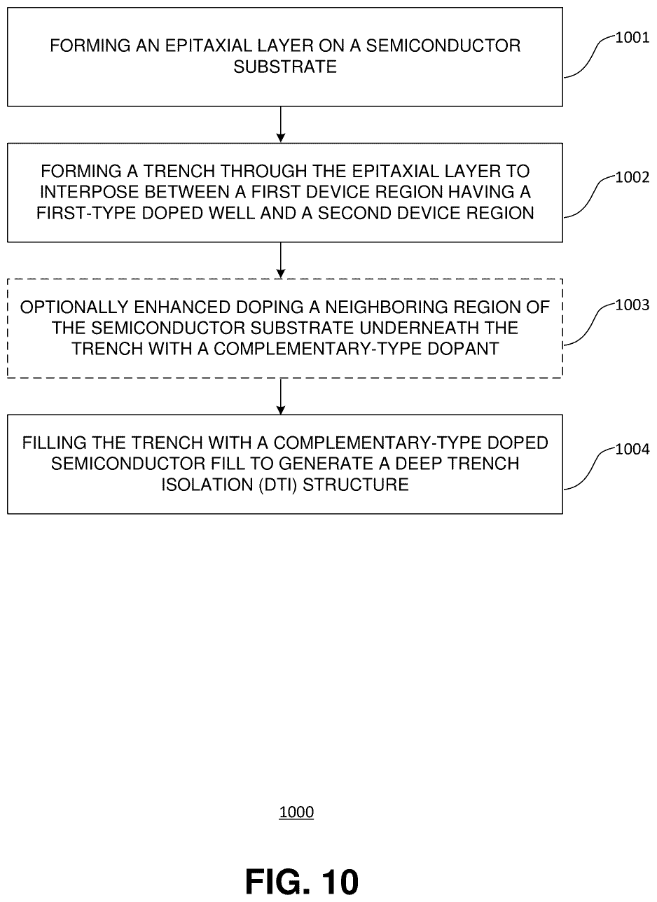

FIG. 10 is a flowchart illustrating a method 1000 of forming a DTI structure in accordance with some embodiments of the disclosure. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included. Acts can correspond, for example, to the structure previously illustrated in FIGS. 2-9 in some embodiments.

At act 1001, an epitaxial layer is formed on a semiconductor substrate. FIG. 2 illustrates a cross-sectional view of some embodiments corresponding to act 1001.

At act 1002, a trench is formed through the epitaxial layer to interpose between a first device region for a first transistor device having a first-type doped well and a second device region. FIGS. 2-7 illustrate cross-sectional views of some embodiments corresponding to act 1002.

At act 1003, enhanced doping is performed in a neighboring region of the semiconductor substrate underneath the trench with a complementary-type dopant. FIG. 8 illustrates a cross-sectional view of some embodiments corresponding to act 1003.

At act 1004, the trench is filled with a complementary-type doped semiconductor fill to generate a deep trench isolation (DTI) structure. FIG. 9 illustrates a cross-sectional view of some embodiments corresponding to act 1004.

Note that multiple subsequent steps (e.g., forming metallization layers and other back end of line (BEOL) steps) may be performed to produce a usable working IC device.

Some embodiments relate to an integrated circuit (IC) structure having a semiconductor substrate, an epitaxial layer on the semiconductor substrate, a first device region having a first transistor device in a first well of doped semiconductor material in the epitaxial layer, a second device region in the epitaxial layer, and a deep trench isolation (DTI) structure interposed between the first device region and the second device region. The DTI structure extends through the epitaxial layer and comprises a doped semiconductor fill.

Some embodiments relate to a method for manufacturing an IC structure. The method includes forming an epitaxial layer on semiconductor substrate, forming a trench through the epitaxial layer to interpose between a first device region for a first transistor device having a first-type doped well and a second device region, and filling the trench with a complementary-type doped semiconductor fill to generate a deep trench isolation (DTI) structure.

Some embodiments relate to an integrated circuit (IC) structure having a low-resistivity P-type semiconductor substrate, an epitaxial layer that is substantially P-type doped on the semiconductor substrate, a first device region comprising a first transistor device in a well of P-type doped semiconductor material in the epitaxial layer, a second region in the epitaxial layer, and a deep trench isolation (DTI) structure interposed between the first device region and the second region. The DTI structure extends through the epitaxial layer and includes a sidewall comprising a dielectric material and an N-type doped semiconductor fill conductively connected to the substrate.

It will be appreciated that in this written description, as well as in the claims below, the terms “first”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) structure comprising:
a semiconductor substrate;
an epitaxial layer on the semiconductor substrate;
a first device region comprising a first transistor device in a first well of doped semiconductor material in the epitaxial layer;
a second device region in the epitaxial layer; and
a deep trench isolation (DTI) structure interposed between the first device region and the second device region, wherein the DTI structure:
extends through the epitaxial layer; and
comprises a doped semiconductor fill.

2. The IC structure of claim 1, wherein the DTI structure comprises dielectric sidewalls interposed laterally between the doped semiconductor fill and the epitaxial layer.

3. The IC structure of claim 1, wherein:
the DTI structure extends into the semiconductor substrate; and
the doped semiconductor fill of the DTI structure is conductively connected to the semiconductor substrate.

4. The IC structure of claim 1, wherein:
the semiconductor substrate is doped with a first-type dopant;
the epitaxial layer is doped with the first-type dopant;
the first well of the first device region is doped with the first-type dopant;
the first transistor device comprises a drain and a source doped with a complementary-type dopant; and
the doped semiconductor fill of the DTI structure is doped with the complementary-type dopant.

5. The IC structure of claim 4, wherein:
the semiconductor substrate comprises a neighboring region contiguous with the doped semiconductor fill; and
the neighboring region is enhanced doped with the complementary-type dopant.

6. The IC structure of claim 1, wherein:
the semiconductor substrate is P-type doped;
the epitaxial layer is P-type doped;
the first well of the first device region is P-type doped;
the first transistor device comprises an N-type doped drain and an N-type doped source formed in the first well; and
the doped semiconductor fill of the DTI structure is N-type doped.

7. The IC structure of claim 6, wherein:
the semiconductor substrate is heavily P-type (P++) doped;
the doped semiconductor fill is enhanced N-type (N+) doped;
the epitaxial layer is lightly P-type (P−) doped; and
a dopant concentration for the P++ doped semiconductor substrate is at least one order of magnitude greater than a dopant concentration for the N+ doped semiconductor fill, which is, in turn, at least one order of magnitude greater than a dopant concentration of the P-doped epitaxial layer.

8. The IC structure of claim 7, wherein:
the first device region further comprises a second well that is N-type doped; and
the second well comprises a second transistor device comprising an enhanced P-type (P+) doped source and an enhanced P-type (P+) doped drain formed therein.

9. The IC structure of claim 6, wherein:
the semiconductor substrate comprises a neighboring region contiguous with the doped semiconductor fill; and
the neighboring region is enhanced N-type (N+) doped.

10. The IC structure of claim 1, wherein the doped semiconductor fill is configured to connect to one of ground or a positive bias.

11. The IC structure of claim 1, wherein the DTI structure forms a moat laterally surrounding the first device region.

12. The IC structure of claim 1, further comprising, in the first device region, a buried doped barrier layer underneath and contacting the first well of doped semiconductor material, wherein:
the first well of doped semiconductor material is doped with a first-type dopant; and
the buried doped barrier layer is doped with a complementary-type dopant.

13. An integrated circuit (IC) structure comprising:
a P-type semiconductor substrate;
an epitaxial layer that is substantially P-type doped on the P-type semiconductor substrate;
a first device region comprising a first transistor device in a well of P-type doped semiconductor material in the epitaxial layer;
a second region in the epitaxial layer; and
a deep trench isolation (DTI) structure interposed between the first device region and the second region, wherein the DTI structure:
extends through the epitaxial layer; and
comprises:
a sidewall comprising a dielectric material; and
an N-type doped semiconductor fill conductively connected to the P-type semiconductor substrate.

14. The IC structure of claim 13, wherein:
the P-type semiconductor substrate comprises a neighboring region underneath, and contiguous with, the N-type doped semiconductor fill of the DTI structure; and
the neighboring region is enhanced N-type (N+) doped.

15. An IC device comprising:
a substrate;
an epitaxial layer on the substrate;
a first device region comprising a first active device in a well of first-type doped semiconductor material in the epitaxial layer;
a second device region in the epitaxial layer; and
a trench isolation structure interposed between the first device region and the second device region, wherein the trench isolation structure comprises a doped semiconductor fill.

16. The IC device of claim 15, wherein the trench isolation structure comprises dielectric sidewalls interposed laterally between the doped semiconductor fill and the epitaxial layer.

17. The IC device of claim 15, wherein:
the substrate is a semiconductor substrate;
the trench isolation structure extends into the semiconductor substrate; and
the doped semiconductor fill is conductively connected to the semiconductor substrate.

18. The IC device of claim 15, wherein:
the doped semiconductor fill is doped with a complementary-type dopant;
the trench isolation structure has a bottom; and
the bottom comprises a neighboring region contiguous with the doped semiconductor fill and enhanced-doped with the complementary-type dopant.

19. The IC device of claim 18, wherein the neighboring region is in the epitaxial layer.

20. The IC device of claim 18, wherein:
the substrate is a semiconductor substrate; and
the neighboring region is in the semiconductor substrate.
